(19) United States
(12) Patent Application Publication
(10) Pub. No.: US 2022/0349051 A1
(43) Pub. Date: Nov. 3, 2022

(54) REACTOR SYSTEMS AND METHODS FOR CLEANING REACTOR SYSTEMS

(71) Applicant: ASM IP Holding B.V., Almere (NL)

(72) Inventors: Amit Mishra, Tempe, AZ (US); Jereld Lee Winkler, Gilbert, AZ (US); Moataz Bellah Mousa, Chandler, AZ (US); Mustafa Muhammad, Gilbert, AZ (US); Paul Ma, Scottsdale, AZ (US); Hichem M'Saad, Paradise Valley, AZ (US); Ying-Shen Kuo, Chandler, AZ (US); Chad Lunceford, Phoenix, AZ (US); Shuaidi Zhang, Chandler, AZ (US)

(21) Appl. No.: 17/729,645

(22) Filed: Apr. 26, 2022

Related U.S. Application Data
(60) Provisional application No. 63/181,700, filed on Apr. 29, 2021.

(51) Int. Cl. C23C 16/44; B08B 7/00; B08B 9/08; B08B 5/00; H01J 37/32

(52) U.S. Cl. CPC C23C 16/4405; B08B 7/0035; B08B 9/08; B08B 5/00; H01J 37/32357; H01J 37/3244; H01J 37/32724; H01J 37/32862; B08B 2209/08

(57) ABSTRACT

A reaction system including a chemical storage assembly in fluid communication with both a remote plasma unit and a bypass line for providing both a plasma activated cleaning species and a non-plasma activated cleaning species to a reaction chamber.

### CROSS-REFERENCE TO RELATED APPLICATIONS

This application is a Non-provisional of, and claims priority to and the benefit of, U.S. Provisional Patent Application No. 63/181,700, filed Apr. 29, 2021 and entitled “REACTOR SYSTEMS AND METHODS FOR CLEANING REACTOR SYSTEMS,” which is hereby incorporated by reference herein.

### FIELD OF INVENTION

The present disclosure generally relates to reactor systems, and particularly reactor systems including assemblies configured for both plasma based and non-plasma based reaction chamber cleaning. The present disclosure also generally relates to methods for cleaning a reaction chamber utilizing both plasma based and non-plasma based cleaning processes.

### BACKGROUND OF THE DISCLOSURE

Vapor-phase reactor systems, such as chemical vapor deposition (CVD), plasma-enhanced CVD (PECVD), atomic layer deposition (ALD), and the like can be used for a variety of applications, including depositing and etching materials on a substrate surface. For example, vapor-phase reactors can be used to deposit and/or etch layers on a substrate to form semiconductor devices, flat panel display devices, photovoltaic devices, microelectromechanical systems (MEMS), and the like.

A typical vapor-phase reactor system includes a reaction chamber, one or more precursor vapor sources fluidly coupled to the reaction chamber, one or more carrier, cleaning and/or purge gas sources fluidly coupled to the reaction chamber, a vapor distribution system to deliver gases (e.g., the precursor vapor(s) and/or carrier, cleaning, and/or purge gas(es)) to a surface of a substrate, and an exhaust source fluidly coupled to the reaction chamber. The system also typically includes a substrate support assembly, such as a susceptor, to hold a substrate in place during processing.

The internal surfaces of a reaction chamber may become contaminated with unwanted material during an extend period of operation of the reactor system and such contamination may result in process drift, and an increase in undesirable defects, for example. Systems and methods are therefore desirable to clean reaction chambers

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

In certain embodiments of the disclosure, a reactor system is provided. The reactor system may include: a reaction chamber, a chemical storage assembly comprising at least one vessel containing a cleaning chemical, and a remote plasma unit fluidly connected to the chemical storage assembly. The reactor system may also include, a gas distribution assembly disposed downstream of the remote plasma unit and configured to receive a plasma activated cleaning species from the remote plasma unit and further introduce the plasma activated cleaning species into a reaction space disposed within the reaction chamber. The reactor system may also include, a bypass line fluidly connecting the chemical storage assembly to the reaction chamber, wherein the bypass line is configured for introducing a non-plasma activated species into the reaction space disposed within the reaction chamber. The reactor system may further include a substrate support assembly disposed within the reaction chamber.

In certain embodiments of the disclosure, a method of cleaning a reactor system is provided. The method may include: providing a reaction chamber including one or more internal surfaces, providing a chemical storage assembly comprising at least one vessel containing a cleaning chemical, flowing the cleaning chemical to a remote plasma unit fluidly connected to the chemical storage assembly, generating a plasma activated cleaning species, introducing the plasma activated cleaning species into a reaction space disposed within the reaction chamber, flowing the cleaning chemical to a bypass line fluidly connecting the chemical storage assembly to the reaction chamber, introducing a non-plasma active cleaning species into the reaction space disposed within the reaction chamber, contacting the one or more internal surfaces with at least one of the plasma activated cleaning species and the non-plasma activated cleaning species, and removing an undesirable material from the one or more internal surfaces.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrate a reactor systems in accordance with exemplary embodiments of the disclosure;

FIG. 2 illustrates data demonstrating the relationship between etch rate and temperature of a substrate support assembly for both radical and thermal etching processes;

FIG. 3 illustrates a plot of process drift before and after a cleaning process; and

FIG. 4 representatively illustrates a portion of the reactor system before and after thermal cleaning.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of systems, methods, structures, devices, and apparatus provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide reactor systems including a reaction chamber and assemblies and components for cleaning said reaction chambers. Exemplary reaction systems can be used, for example, to clean a reaction chamber employing both plasma activated cleaning species (e.g., radical based cleaning processes) and non-plasma activated cleaning species (e.g., thermal based cleaning process).

To maintain high process availability of a process module of a reactor system, reaction chamber cleaning can be necessary to remove unwanted build up of material on internal reaction chamber surface. The removal of unwanted material can be performed employing an etch process with the selectivity of the etch process being at least temperature driven. For example, to maintain electrostatic chucking of a substrate disposed within a reaction chamber, periodic preferential etching of the surfaces of the electrostatic chuck can be required during normal operation periods and a further etching process can be required for periodically cleaning the internal walls of the reaction chamber. The embodiments of the disclosure, include systems and methods for cleaning a reaction chamber by a less aggressive process, thereby preventing damage to assemblies and components disposed within the reaction chamber and allowing for a shorter period of time post cleaning for recovery of the reaction chamber to a normal operating condition. The embodiments include systems and methods allowing for preferential etching according to the temperature of the internal surfaces within the reaction chamber.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert gases include helium, argon, and any combination thereof. In some cases, an inert gas can include nitrogen and/or hydrogen.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or dielectric material layer overlying at least a portion of the bulk semiconductor material.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each deposition cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more deposition cycles, e.g., during each step of each cycle, to remove any excess precursor from the process chamber and/or remove any excess reactant and/or reaction byproducts from the reaction chamber.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

The embodiments of the present disclosure may include assemblies, components and methods that enable the delivery of a cleaning chemistry (e.g., an etch chemistry) into a reaction chamber through both a gas distribution assembly (e.g., a showerhead type assembly) as well through a bypass line which circumvents the gas distribution assembly. In addition, a gas curtain may formed via an inert gas flow proximate to the gas distribution assembly to provide a protective gas curtain over an exposed surface of the gas distribution assembly.

The embodiments of the present disclosure may include assemblies, components, and methods for providing a cleaning chemistry (e.g., an etch chemistry) that can be highly thermally activated (i.e., low or zero etch rate at low temperatures and high etch rate at elevated temperature). Such a highly thermally activated etch chemistry can preferentially remove unwanted material from surfaces at elevated temperatures in comparison to surfaces at reduced temperatures thereby preventing unwanted damage to select surfaces within the reaction chamber. In addition, a thermally activated cleaning chemistry can be utilized to, at least in part, rapidly remove an unwanted film or material on a surface of a substrate support. In some cases, the substrate support may comprise an electrostatic chuck, and in such cases, the thermally activated cleaning chemistry may restore the chucking capacity of the electrostatic chuck.

In various embodiments, the thermally activated cleaning chemistry may etch or, in some cases, remove various metals, such as molybdenum, tungsten, vanadium, copper, ruthenium, and the like from the substrate support and/or other surfaces within the reaction chamber. Additionally, or alternatively, the thermally activated cleaning chemistry may etch or, in some cases, remove various nitrides, such as titanium nitride (TiN), molybdenum nitride (MoN), tungsten nitride (WN), and the like from the substrate support and/or other surfaces within the reaction chamber.

The embodiments of the present disclosure may also include assemblies, components, and methods for providing an etch chemistry that may be plasma activated to form radical cleaning species from a plasma generation device.

The embodiments of the present disclosure may also include assemblies, components, and methods for employing a thermal cleaning process (e.g., a thermal etching process) that is used on a frequent basis to clean unwanted deposition preferentially from certain internal surfaces (such as the exposed surfaces of a substrate support assembly) and a plasma cleaning process (e.g., a radical based cleaning process) that is used on an infrequent basis to clean the entire internal surfaces of the reaction chamber. The combination of both a preferential thermal cleaning process and a radical based cleaning process can result in an increase in the availability of the reactor system, e.g., an increase in the operative time (“up-time”) between maintenance cycles.

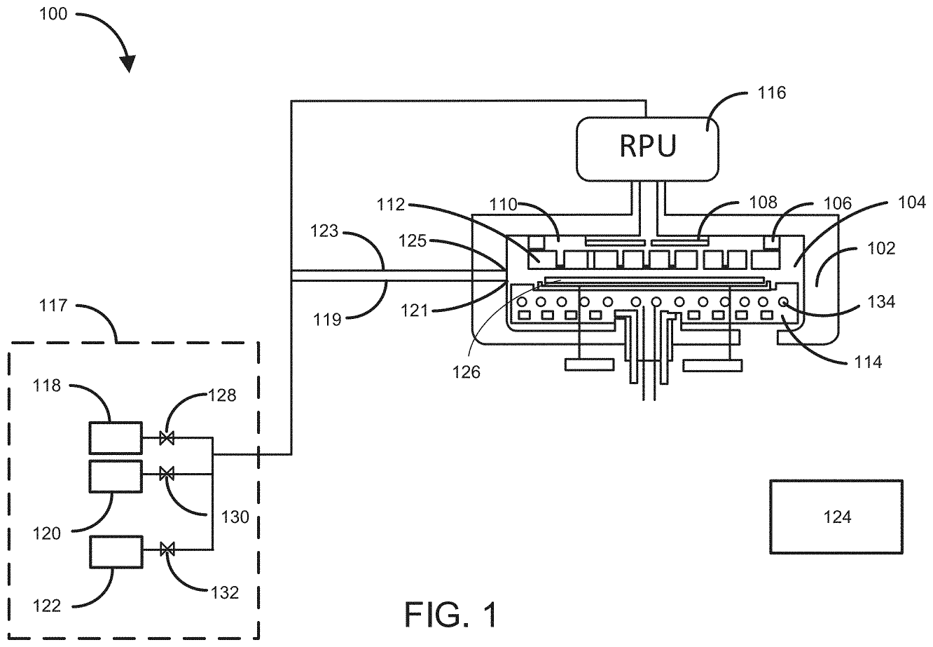

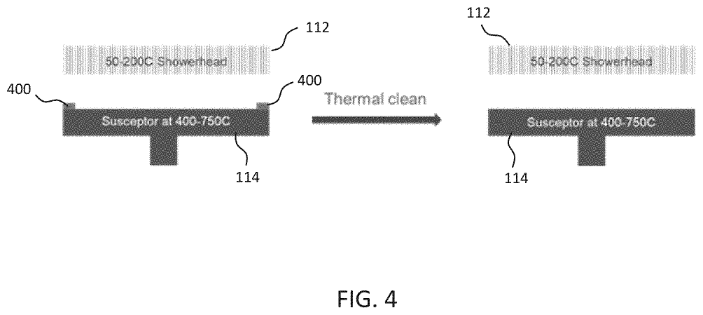

FIG. 1 illustrates a reactor system 100 in accordance with exemplary embodiments of the disclosure. The reactor system 100 illustrated in FIG. 1 is a simplified schematic and therefore the exemplary reaction system 100 of the current disclosure may include further components and assemblies (not illustrated), such as, for example, values, flow controllers, pressure controllers, heaters, gas channels, and gas sources, etc. The reactor system 100 includes a reaction chamber 102. Disposed within the reaction chamber is a reaction space 104 and a substrate support assembly 114. The reaction chamber 102 can include one or internal surfaces and such surfaces may be partially or fully coated with an undesirable material or film. For example, the undesirable material (material deposits 400 (FIG. 4)) may build up along the edge of the substrate support assembly 114. The one or more internal surfaces within the reaction chamber 102 can include an exposed surface of a chamber wall and an exposed surface of the substrate support assembly 114. The substrate support assembly 114 can include one or more heaters 134 configured for heating the substrate support assembly to a temperature to enable preferential cleaning of exposed surfaces of the substrate support assembly. The substrate support assembly 114 can include an exposed surface comprising a ceramic surface. Alternatively, or additionally, the substrate support assembly 114 may comprise a metal material. In some embodiments of the disclosure, the substrate support assembly 114 can comprise an electrostatic chuck.

The reactor system 100 includes a chemical storage assembly 117. The chemical storage assembly 117 can include one or more vessels for containing cleaning chemicals(s), precursors(s), carrier gas, and/or purge gas. The chemical storage assembly 117 can include at least one vessel for containing a cleaning chemical. In some embodiments, the chemical storage assembly 117 can include a first vessel 118 (and associated flow controller 128) containing a first cleaning chemical. In some embodiments, the chemical storage assembly 117 may further comprise a second vessel 120 (and associated flow controller 130) containing a second cleaning chemical. The chemical storage assembly 117 may comprise further vessels containing additional cleaning chemicals. The chemical storage assembly 117 may comprise vessels configured for storing and supplying one or more cleaning chemicals selected from the group consisting of: NF₃, BCl₃, CCl₄, XeF₃, F₂, NOF, F₂, and NO₂F.

The reactor system 100 can include a plasma generation device, such as, a remote plasma unit 116, for example. The remote plasma unit 116 can be fluidly connected to the chemical storage assembly 117. In some embodiments, the remote plasma unit can be disposed downstream of the chemical storage assembly 117 and upstream of the reaction chamber 102.

The reactor system 100 can include a bypass line 119 fluidly connecting the chemical storage assembly 117 to the reaction chamber 102 via a first reaction chamber inlet 121. The bypass line 119 can be configured for introducing a non-plasma activated cleaning species into the reaction space 104 disposed within the reaction chamber 102. For example, the non-plasma activated cleaning species may comprise a highly thermally activated cleaning chemistry utilized for preferentially etching surfaces within the reaction chamber at elevated temperature in comparison to internal reaction chamber surfaces at lower or reduced temperatures.

In some embodiments, the chemical storage assembly 117 may include a single cleaning vessel, containing a single cleaning chemical, in fluid communication with both the remote plasma unit 116, and the bypass line 119. In some embodiments, the chemical storage assembly 117 may include a first vessel 118 containing a first cleaning chemical and a second vessel 120 containing a second cleaning chemical, wherein the first cleaning chemical is different from the second cleaning chemical. In some embodiments, the first vessel can be in fluid communication with the remote plasma unit 116 and the second vessel can be in fluid communication with the bypass line 119.

In some embodiments, the bypass line 119 fluidly connects a vessel containing a cleaning chemical to the first reaction chamber inlet 121. For example, the first reaction chamber inlet 121 may be disposed distal to a gas distribution assembly 106.

The reactor system 100 also includes a gas distribution assembly 106, including a gas distribution device 108, a gas expansion area 110, and a showerhead plate 112. The gas distribution assembly 106 is coupled to the remote plasma unit 116 and receives activated species from the remote plasma unit 116, distributes the activated species within gas expansion area 110, and provides the activated species to the reaction space disposed within the reaction chamber via the showerhead plate 112. The gas distribution assembly 106, gas expansion area 110, and showerhead plate 112 can be used to distribute the activated species in a desired manner to provide, for example, a desired amount, flowrate, or flux of the activated species to the internal surfaces of the reaction chamber.

Remote plasma unit 116 generates activated species (e.g., radicals) from one or vessels (118, and 120) provided from the chemical storage assembly 117. The generated radicals then enter the reaction chamber 104 through gas distribution assembly 106 and then flow into reaction chamber 102. The remote plasma source may include: a toroidal style ICP and/or CCP source or a coil style ICP source driven by different RF frequencies, such as a 100 kHz, 400 kHz, 2 MHz, 13.56 MHz, 60 MHz, 160 MHz and/or 2.45 GHz microwave source.

The reactor system 100 can also include a second reaction chamber inlet 125 in fluid communication with chemical storage assembly 117 via gas channel 123. The second reaction chamber inlet 125 can be disposed below the gas distribution assembly 106 and can be configured to direct an inert gas stream towards a surface of the gas distribution assembly 106. For example, the chemical storage assembly may comprise a third vessel 122 (and an associated flow control valve 132), wherein the third vessel 122 contains an inert gas (e.g., nitrogen, or argon). The inert gas may be provided to the second reaction chamber inlet 125 and directed into the reaction chamber 102 towards a lower surface of the gas distribution assembly 106, and particularly towards the lower surface of the showerhead plate 112. The inert gas stream can provide a curtain of protective gas across the lower surface of the showerhead plate. For example, a protective gas curtain may be employed when performing a preferential thermal etch of exposed surfaces of the substrate support assembly 126.

The reactor system 100 also includes a controller 124 that can be configured to perform various functions and/or steps as described herein. The controller 124 can include one or more microprocessors, memory elements, and/or switching elements to perform the various functions. Although illustrated as a single unit, the controller 124 can alternatively comprise multiple devices. By way of examples, the controller 124 can be used to control gas flow (e.g., by monitoring flow rates and controlling valves 128, 130, 132), motors, and/or control heaters, such as one or more of the heaters 134, and the like).

In some embodiments of the disclosure, the reactor system 100 can be configured for performing a cyclical deposition process, such as, for example, atomic layer deposition, or cyclical chemical vapor deposition. In some embodiments, the reactor system 100 can be configured for performing atomic layer deposition of a film onto a surface of a substrate disposed upon the substrate support assembly disposed within the reaction chamber 102. As a non-limiting example, the reactor system 100 may be configured for the deposition of a film, such as, a metal, a metal nitride, or a metal carbide, onto a surface of a substrate. The deposited film may be utilized for the fabric of an electronic device, such as, for example, logic devices (e.g., CMOS devices), and/or memory devices (e.g., NAND devices)

The present disclosure further includes methods for cleaning a reaction chamber. For example, a cleaning method may comprise: providing a reaction chamber including one or more internal surfaces, providing a chemical storage assembly comprising at least one vessel containing a cleaning chemical, flowing the cleaning chemical to a remote plasma unit fluidly connected to the chemical storage assembly, generating a plasma activated cleaning species, introducing the plasma activated cleaning species into a reaction space disposed within the reaction chamber, flowing the cleaning chemical to a bypass line fluidly connecting the chemical storage assembly to the reaction chamber, introducing a non-plasma activated cleaning species into the reaction space disposed within the reaction chamber, contacting the one or more internal surfaces with at least one of the plasma activated cleaning species and the non-plasma activated cleaning species; and removing an undesirable material from the one or more internal surfaces.

In some embodiments of the cleaning methods, the one or more internal surfaces within the reaction chamber may comprise at least one chamber wall and a substrate support assembly. The chamber walls may be at a first temperature and the substrate support assembly may be at a second temperature, wherein the second temperature is greater than the first temperature. The chamber walls may be a temperature between approximately 100° C. and 200° C., or between 120° C. and 180° C., or between 140° C. and 170° C. The substrate support assembly, and particularly an exposed surface of the substrate support assembly, may be at a temperature between approximately 400° C. and 700° C.

The cleaning methods of the current disclosure may comprise a chemical storage assembly comprising a first vessel containing a first cleaning chemical and second vessel containing a second cleaning chemical, wherein the first cleaning chemical is different to the second cleaning chemical. For example, the first vessel can be in fluid communication with a remote plasma unit and the second vessel can be in fluid communication with a bypass line. In some embodiments, the chemical storage assembly comprises a single cleaning vessel containing a single cleaning chemical that can be in fluid communication with both the remote plasma unit and the bypass line. In some embodiments, the cleaning chemical can comprise a halide containing cleaning chemical, such as, for example, NF₃, BCl₃, CCl₄, XeF₃, F₂, NOF, F₂, and NO₂F. In some embodiments, the plasma activated cleaning species can be introduced into the reaction chamber for a first time period and the non-plasma activated cleaning species can be introduced into reaction chamber for a second time period, the wherein first time period and the second time period are non-concurrent, i.e., the plasma activated cleaning species and the non-plasma activated cleaning species and not introduced into the reaction chamber at the same time. In alternative embodiments, the plasma activated cleaning species and non-plasma activated cleaning species may be introduced into the reaction chamber concurrently, i.e., at the same time period, or at least with an overlapping period of time.

In some embodiments, the non-plasma activated cleaning species may be introduced into the reaction chamber with a first frequency and the plasma activated cleaning species may be introduced into the reaction chamber with a second frequency, wherein the second frequency is less than the first frequency.

In some embodiments, the non-plasma activated cleaning species may be introduced into the reaction chamber whilst maintaining the surface temperature of the substrate support assembly above 300° C., or above 500° C., or above 700° C., or between a temperature between 50° C. and 750° C. In addition, as well maintaining the temperature of the substrate support assembly during introduction of the non-plasma activated cleaning species, the temperature of the other internal wetted surfaces of the reaction chamber (e.g., such as the chamber walls) may be maintained at temperature of less than 300° C., or less than 250° C., or less than 200° C., or less than 150° C., or less than 100° C., or even between 300° C. and 100° C. In some embodiments, the temperature difference between the substrate support assembly (e.g., the surface temperature of an electrostatic chuck) and the other wetted internal surfaces of the reaction chamber may be greater than 100° C., or great than 200° C., or greater than 300° C., or greater than 400° C., or greater than 500° C., or even greater than 600° C. For example, the temperature delta between the surface temperature of the substrate support assembly and the other internal wetted surfaces of the reaction chamber can be utilized to rapidly remove a thick build-up of unwanted material from a surface of the substrate support assembly, thereby allowing for a rapid post-clean recovery of the substrate support assembly to operational conditions, such as, for example, recovering the chucking capability of a substrate support assembly comprising an electrostatic chuck.

In addition, during the introduction of the non-plasma activated cleaning species into the reaction chamber, an inert gas purge curtain may be introduced proximate to, or even contacting, a lower surface of the showerhead plate 112, thereby providing a protective inert gas stream to the showerhead plate 112.

In some embodiments, the non-plasma activated cleaning species may preferentially remove (i.e., etch) an undesirable film or material from an exposed surface of a substrate support assembly in comparison to an undesirable film or material exposed on the chamber walls of the reaction chamber. In other words, the cleaning processes may remove an undesirable film from an exposed surface of a substrate support assembly at a higher rate than an undesirable film disposed over one or more chamber walls of the reaction chamber.

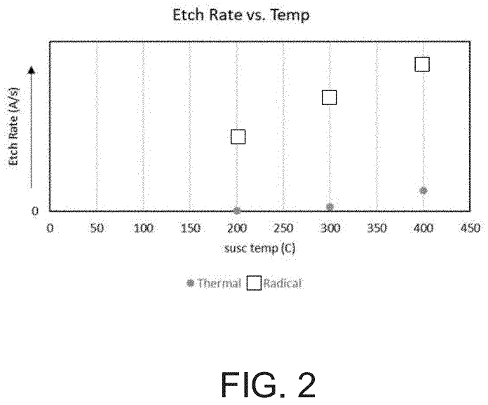

For example, FIG. 2 illustrates data demonstrating the etch rate versus the temperature of the substrate support assembly, i.e., the susceptor temperature, employing both activated cleaning species generated by a plasma and thermally activated cleaning species. The data in FIG. 2 clearly demonstrates that for a particular susceptor temperature, there is clear etch selectivity (difference in etch rate) between the radical cleaning method and the thermal cleaning method.

In addition, and referring to FIG. 4, embodiments of the present technology are able to etch material deposits from some components at a higher rate than other components. In particular, components that have a higher temperature (e.g., above 300 C) at the time of the thermal cleaning exhibit a higher etch rate than components having a lower temperature (e.g., 200 C). For example, before thermal cleaning, material deposits 400 may be observed on the edges on the substrate support assembly 114, while only minimal deposits may be observed on the showerhead plate 112. The thermal cleaning process may remove the material deposits from the substrate support assembly 114 at a rate of more than 40 A/second, while the thermal cleaning process does not remove any material deposits from the showerhead plate 112.

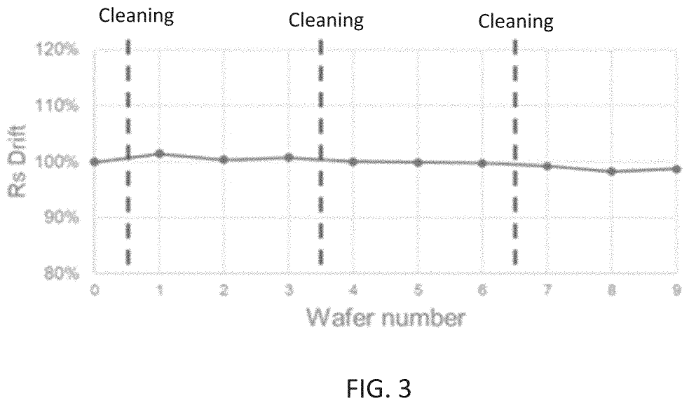

In various embodiments, and referring to FIG. 3, after the cleaning step (e.g., radical cleaning and/or thermal cleaning), the reaction chamber may not require subsequent conditioning. In conventional systems, chamber conditioning may be required before a new wafer can be transferred into the chamber for a new deposition process. After a conventional cleaning, and before conditioning, a process drift of up to 150% to 200% is typically observed. Process drift negatively impacts the recovery of the reaction chamber to normal processing conditions. This process drift may be corrected by running a deposition process on a “dummy wafer” (also referred to as conditioning), however, this additional step (i.e., transfer of a dummy wafer and running additional deposition) decreases the operative time of the system.

According to embodiments of the present technology, the process drift after cleaning is minimal (i.e., +/−5%), and therefore conditioning with a dummy wafer is not required, which increases the operative time of the system. Specifically, in a case where the chamber is used to deposit MoN and molybdenum, a resistivity (Rs) drift (i.e., process drift) of a MoN film can be measured.

In conventional cleaning, the first few wafers of MoN deposition will have abnormally high electrical resistivity due to impacts of the cleaning chemicals, such as fluorine. However, according to embodiments of the present technology, the resistivity drift of the MoN film after a cleaning process is minimal (i.e., +/−5%); therefore, chamber conditioning that involves running a deposition process on a dummy wafer is not necessary to recover the chamber to normal processing conditions. According to embodiments of the present technology, after the cleaning process is complete and before a new dp, a fluorine scavenger may be introduced into the chamber to enhance recovery of the chamber to normal operating conditions.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A reactor system comprising:
a reaction chamber;
a chemical storage assembly comprising at least one vessel containing a cleaning chemical;
a remote plasma unit fluidly connected to the chemical storage assembly;
a gas distribution assembly disposed downstream of the remote plasma unit and configured to receive a plasma activated species from the remote plasma unit and further introduce the plasma activated species into a reaction space disposed within the reaction chamber;
a bypass line fluidly connecting the chemical storage assembly to the reaction chamber, wherein the bypass line is configured for introducing a non-plasma activated species into the reaction space disposed within the reaction chamber; and
a substrate support assembly disposed within the reaction chamber.

2. The system of claim 1, wherein the substrate support assembly comprises one or more heating elements.

3. The system of claim 1, wherein the substrate support assembly comprises an exposed ceramic surface.

4. The system of claim 1, wherein the substrate support assembly comprises an electrostatic chuck.

5. The system of claim 1, wherein the bypass line fluidly connects the at least one vessel containing the cleaning chemical to a first reaction chamber inlet.

6. The system of claim 1, wherein the first reaction chamber inlet is disposed distal to the gas distribution assembly.

7. The system of claim 1, further comprising a second reaction chamber inlet in fluid communication with the chemical storage assembly, wherein the second reaction chamber inlet is disposed below the gas distribution assembly and is configured to direct an inert gas stream towards a surface of the gas distribution assembly.

8. The system of claim 1, wherein the chemical storage assembly comprises a first vessel containing a first cleaning chemical and a second vessel containing a second cleaning chemical, wherein the first cleaning chemical is different to the second cleaning chemical.

9. The system of claim 1, wherein the first vessel is in fluid communication with the remote plasma unit and the second vessel is in fluid communication with the bypass line.

10. The system of claim 1, wherein the chemical storage assembly comprises a single cleaning vessel containing a single cleaning chemical and the single cleaning vessel is in fluid communication with both the remote plasma unit and the bypass line.

11. A reactor system, comprising:
a reaction chamber including at least one chamber wall;
a chamber cleaning assembly configured for supplying both radical cleaning species and non-radical cleaning species to the reaction chamber, the chamber cleaning assembly comprising;
a chemical storage assembly comprising at least one vessel containing a cleaning chemical,
a first fluid channel fluidly connecting the chemical storage assembly vessel to the reaction chamber, wherein the first fluid channel comprises a plasma generation device disposed downstream of the reaction chamber; and
a second fluid channel fluidly connecting the chemical storage assembly to the reaction chamber; and
a substrate support assembly disposed within the reaction chamber.

12. A method of cleaning a reactor system, comprising:
providing a reaction chamber comprising a first internal surface and a second internal surface;
providing a chemical storage assembly comprising at least one vessel containing a cleaning chemical;
flowing the cleaning chemical to a remote plasma unit fluidly connected to the chemical storage assembly;
generating a plasma activated cleaning species; and
removing an undesirable material from the first internal surface at first rate and removing the undesirable material from the second internal surface at a second rate, wherein the first rate is higher than the second rate, and wherein removing the undesirable material comprises:
introducing the plasma activated cleaning species into a reaction space disposed within the reaction chamber;
flowing the cleaning chemical to a bypass line fluidly connecting the chemical storage assembly to the reaction chamber,
introducing a non-plasma active cleaning species into the reaction space disposed within the reaction chamber; and
contacting the one or more internal surfaces with at least one of the plasma activated cleaning species and the non-plasma activated cleaning species.

13. The method of claim 12, wherein the first internal surface comprises a substrate support assembly and the second internal surface comprises a chamber wall.

14. The method of claim 12, wherein the chemical storage assembly comprises a first vessel containing a first cleaning chemical and second vessel containing a second cleaning chemical, wherein the first cleaning chemical is different to the second cleaning chemical.

15. The method of claim 12, wherein the first vessel is in fluid communication with the remote plasma unit and the second vessel is in fluid communication with the bypass line.

16. The method of claim 12, wherein the chemical storage assembly comprises a single cleaning vessel containing a single cleaning chemical.

17. The method of claim 12, wherein the single cleaning vessel is in fluid communication with both the remote plasma unit and the bypass line.

18. The method of claim 12, wherein the cleaning chemical is selected from the group consisting of: NF₃, BCl₃, CCl₄, XeF₃, F₂, NOF, F₂, and NO₂F.

19. The method of claim 12, wherein the non-plasma activated cleaning species is introduced into the reaction chamber with a first frequency and the plasma activated cleaning species is introduced into the reaction chamber with a second frequency, wherein the second frequency is less than the first frequency.

20. The method of claim 12, wherein a process drift following the removal of the undesirable material is +/−5%.
